(19) United States
(12) Patent Application Publication
(10) Pub. No.: US 2008/0180901 A1
(43) Pub. Date: Jul. 31, 2008

(54) SUPPORTING APPARATUS WITH SHOCK ISOLATION FUNCTION

(75) Inventor: Shou-Jen Yang, Taipei (TW)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: Inventec Corporation, Taipei (TW)

(21) Appl. No.: 11/668,782

(22) Filed: Jan. 30, 2007

(51) Int. Cl. H05K 5/02

(52) U.S. Cl. 361/685

(57) ABSTRACT

A supporting apparatus with a shock isolation function is provided, which is applicable for supporting at least one storage device. The supporting apparatus includes a frame body for accommodating a storage device and at least two supporting parts. The frame body has at least two side plates, and a protruding point is protruded respectively from each side plate. The supporting part has a main body and an elastic washer sleeved on an outer edge of the main body. The main body has at least one joint hole for the protruding point to be engaged in, such that the main body is fixed on the side plate, and the elastic washer mutually contacts with the storage device, so as to absorb the shocking energy.

### BACKGROUND OF THE INVENTION

1. Field of Invention

The present invention relates to a fixing structure of a storage device. More particularly, the present invention relates to a fixing apparatus with a shock isolation function.

2. Related Art

Generally, at least one non-volatile storage device, for example, a hard disc and an optical disc drive, is disposed in a computer, so as to store an operating system for performing functions of the computer and to read and write a great number of data files. Therefore, in the case of the computer, a fixing apparatus is designed, so as to fix the storage device in the case.

For the hard disc, the common conventional method of fixing the hard disc is using a plurality of screws to directly lock the hard disc on the hard disc frame in the case. Alternately, firstly, a sheet metal punching process is performed on two opposite side plates of the hard disc frame, and thus, they are bent into a positioning holder with folded flanges and a fixing base, such that the positioning holder supports the hard disc. Then, a catch part is respectively installed on the side surface of the hard disc, for being mutually buckled with the fixing base, so as to support and fix the hard disc in the hard disc frame.

Before the catch part is installed, it is necessary to firstly process the frame work to form the positioning holder and the fixing base vertically bending towards the side plate. Since the supporting holder and the fixing base are directly formed on the side plate by means of hollowing out, and the hard disc device is locked through the conventional screwing method, the two methods both result in that the frame work only has a utilizing space on one side, and the other side of the side plate cannot lock and fix additional storage devices. For the working station with a plurality of hard discs, such as a server, a plurality of additional frame works must be disposed for positioning a great number of hard discs, such that the computer frame work occupies an excessive large space.

In order to make the hard disc frame for fixing the hard disc have a certain structural strength, it is mostly made of a rigid material, and directly fixed in the case. The conventional storage device such as the hard disc or the optical disc drive is mutually contacted with and fixed on the hard disc frame directly. If the computer is carelessly crashed down or dropped to the ground, the crashing force impinged on the hard disc frame is directly transmitted to the storage device, such that the storage device is easily damaged or even destroyed.

In addition, it is extremely easy for the micro-shocking energy generated by the operation of the storage device to mutually generate a resonance effect with the hard disc frame. Furthermore, under the synergistic effect with the resonance frequency in the internal space of the computer, the generated resonance noise is quite serious. The storage devices are easily crashed with each other due to the resonance of the frame work, so as to reduce the service life of the storage device.

### SUMMARY OF THE INVENTION

The conventional frame for fixing storage devices lacks of a buffering function, such that the storage device is easily damaged due to the shock effect, and the structural design of the frame is not helpful for the storage device to be allocated side by side. In view of the above problems, the present invention provides a supporting apparatus with a shock isolation function, which is not only capable of enlarging the utilizing space of the frame work of the computer, and the shocking energy is absorbed, so as to prevent the storage device from being destroyed.

The supporting apparatus with the shock isolation function of the present invention is used to support at least one storage device, and includes a frame body and a plurality of supporting parts disposed in pairs. The frame body is used to accommodate a storage device and has a plurality of side plates, and at least one protruding point is respectively protruded from two sides of each side plate. Each supporting part has a main body and an elastic washer. The main body of each supporting part has at least one joint hole for the protruding point to be engaged in, such that each supporting part is fixed on two neighboring side plate in pairs, and each pair of supporting parts supports the bottom surface of the storage device at two sides of the storage device. The elastic washer is sleeved on an outer periphery of the main body and contacts with the storage device, for absorbing and isolating the shock.

The effect of the present invention lies in that, a plurality of alternately arranged protruding points is respectively formed on two opposite side surfaces of the side plate for the frame body, and at least one supporting part is fixed on the side surface of the side plate, so as to form a plurality of spaces for supporting and accommodating the storage device. The utilizing space in the frame body is increased, and the supporting part mutually contacted with the storage device further provides a shock absorbing protection function, so as to prevent the storage device from being affected by the shocking energy and being destroyed.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below for illustration only, which thus is not limitative of the present invention, and wherein:

FIG. 1 is a schematic exploded view of a first embodiment of the present invention;

FIG. 2 is a combined stereogram of the first embodiment of the present invention;

FIG. 3 is a schematic sectional view of the first embodiment of the present invention;

FIG. 4 is a schematic exploded view of a second embodiment of the present invention;

FIG. 5 is a combined stereogram of the second embodiment of the present invention; and

FIG. 6 is a schematic sectional view of the second embodiment of the present invention.

### DETAILED DESCRIPTION OF THE INVENTION

The supporting apparatus with the shock isolation function according to the present invention is used to support one or a plurality of storage devices. The storage device includes (but not limited to) non-volatile storage devices fixed in a case of a computer, such as hard disc drives, soft disc drives, optical disc drives, and CD/DVD burners. In the following detailed description of the present invention, the hard disc drive is taken as the most preferred embodiment of the present invention. However, the accompanying drawings are only provided for reference and illustration, but not used to limit the present invention.

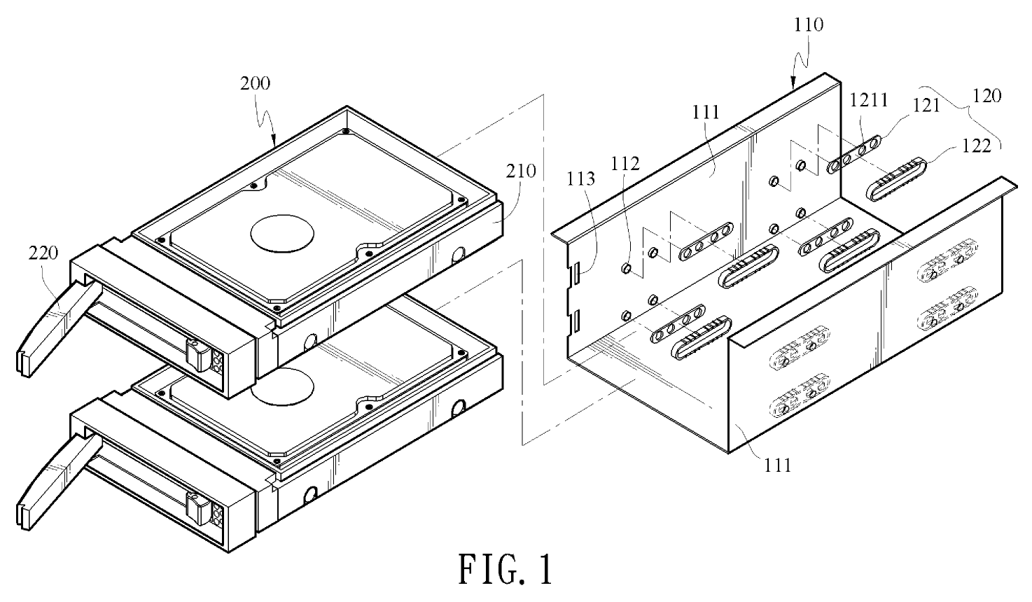

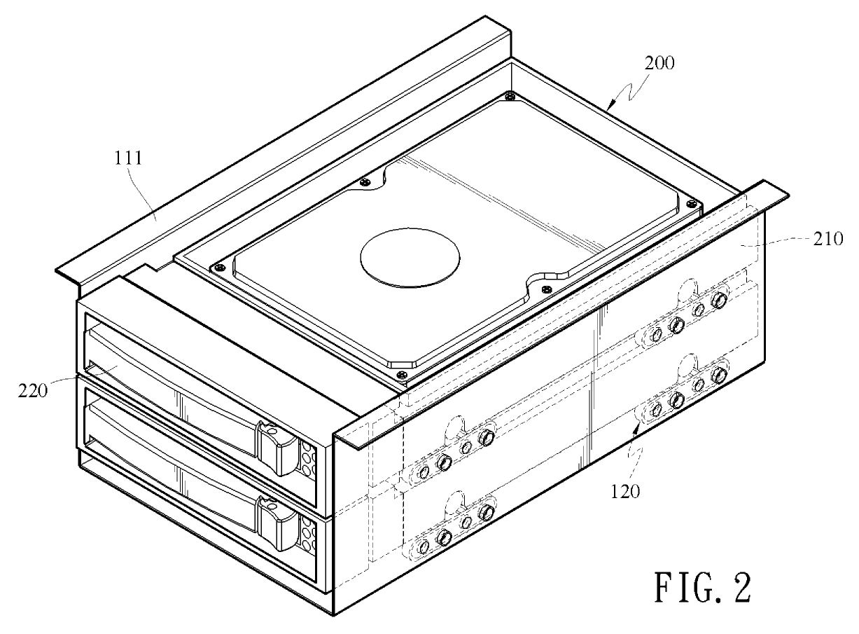

FIGS. 1 and 2 show the supporting apparatus with the shock isolation function according to a first embodiment of the present invention. It is used to support one or a plurality of storage devices 200. The supporting apparatus includes a frame body 110 and at least two supporting parts 120. The frame body 110 has two opposite side plates 111 that are spaced apart to form an accommodating space with the same width as that of the storage device 200, for accommodating the storage device 200 between two side plates 111. A plurality of protruding points 112 is respectively protruded from side surfaces of the two side plates 111 that are facing each other, and the protruding points 112 are equidistantly spaced apart from each other. A plurality of groups of protruding points 112 is selectively disposed on the side plate 111 at a height satisfying the size of the storage device 200. The supporting part 120 has a main body 121 and an elastic washer 122 made of rubber, and the main body 121 has a joint hole 1211 corresponding to the protruding point 112, for the protruding points 112 of the side plate 111 to be engaged in, such that two supporting parts 120 are respectively fixed on side surfaces of two side plates 111 that are facing each other. According to the practical number of the storage devices 200, a plurality of supporting parts 120 is alternately disposed along the longitudinal direction, such that a space for accommodating a single storage device 200 is formed between the neighboring upper and lower supporting parts 120. When the storage device 200 is placed between two side plates 111, the two supporting parts 120 just support the bottom surface of the storage device 200 at two sides of the storage device 200. The elastic washer 122 is sleeved on the outer periphery of the main body 121, and mutually contacts with the storage device 200, so as to absorb the external shocking energy, or the shocking energy generated by the storage device 200 itself.

Referring to FIGS. 1 and 2, the protruding points 112 on the side plate 111 are formed by mean of directly performing the punching process on predetermined positions of the side plate 111, such that the punched parts on the side plate 111 are formed into the protruding points 112. In addition, two ends of the main body 121 of the supporting part 120 are fabricated as circular arc-shaped. If some deviation in position or angle occurs when the storage device 200 is pushed into the frame body 110, the main body 121 with the circular arc-shaped end surfaces may guide slide tracks 210 at two sides of the storage device 200 to smoothly slide to a position above the supporting parts 120, such that the supporting parts 120 support the storage device 200 in the accommodating space formed by two side plates. A fixing component 220 pivoted to an end of the storage device 200 is buckled to the positioning hole 113 at the edge of the side plate 111, such that the storage device 200 may be fixed in the frame body 110 and may not loose.

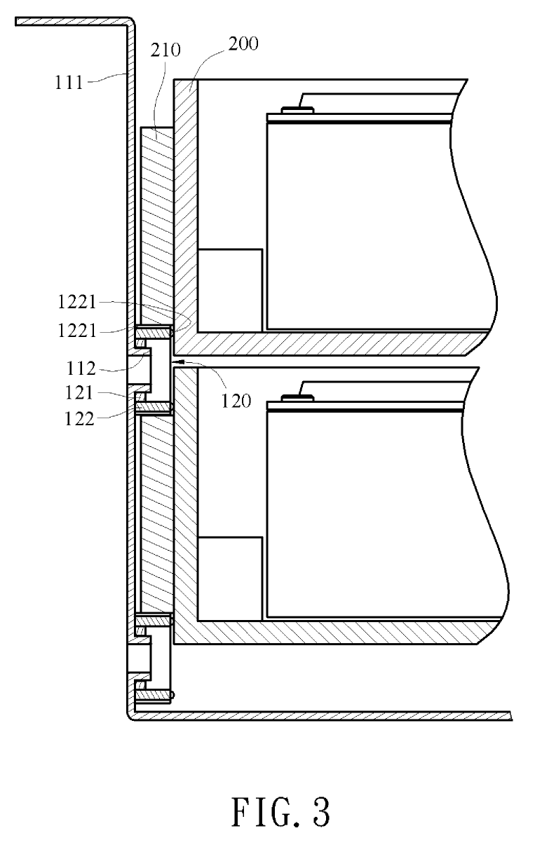

As shown in FIG. 3, it is a schematic sectional view of the first embodiment. The elastic washer 122 of the supporting part 120 is used to absorb the shocking energy conducted to the storage device 200 from the exterior, or the shocking energy generated during the operation of the storage device 200. The elastic washer 122 is formed with at least one rib-shaped shock absorbing portion 1221 relative to the upper and lower surfaces of the side plate 111 in the vertical direction, and mutually contacts with the slide tracks 210 of the side edge of two neighboring storage devices 200, thereby increasing the deformation of the elastic washer 122, and improving the effect of absorbing the shocking energy of the elastic washer 122. When the supporting part 120 is fixed on the side plate 111, the height of the elastic washer 122 sleeved on the outer edge of the main body 121 protruding from the side plate 111 is larger than the height of the main body 121 protruding from the side plate 111, so as to wrap the main body 121 in the elastic washer 122. A plurality of shock absorbing portions 1221 with the shape similar to protruding points is disposed on the side peripheral surface of the elastic washer 122 in the horizontal direction relative to the side plate 111, and mutually contacts with the side edge of the neighboring storage device 200, so as to prevent the storage device 200 from directly contacting with the main body 121 or the side plate 111, such that the shock energy can be absorbed, and the energy must be transmitted through the elastic washer 122 to the side plate 111 and the storage device 200, thereby enhancing the shock isolation and absorbing effect of the elastic washer 122.

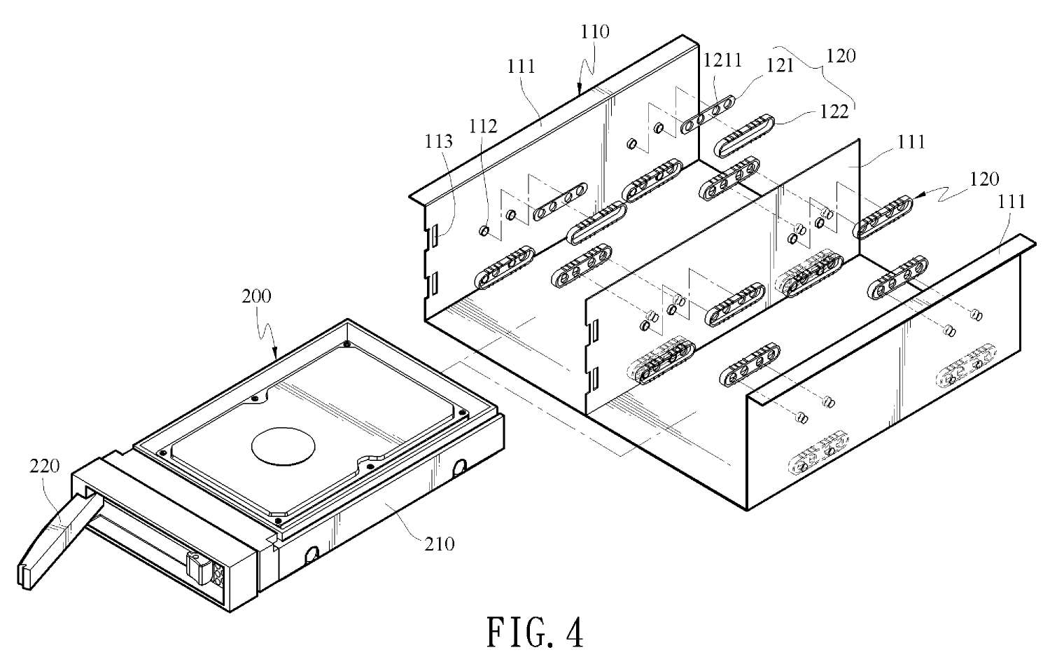

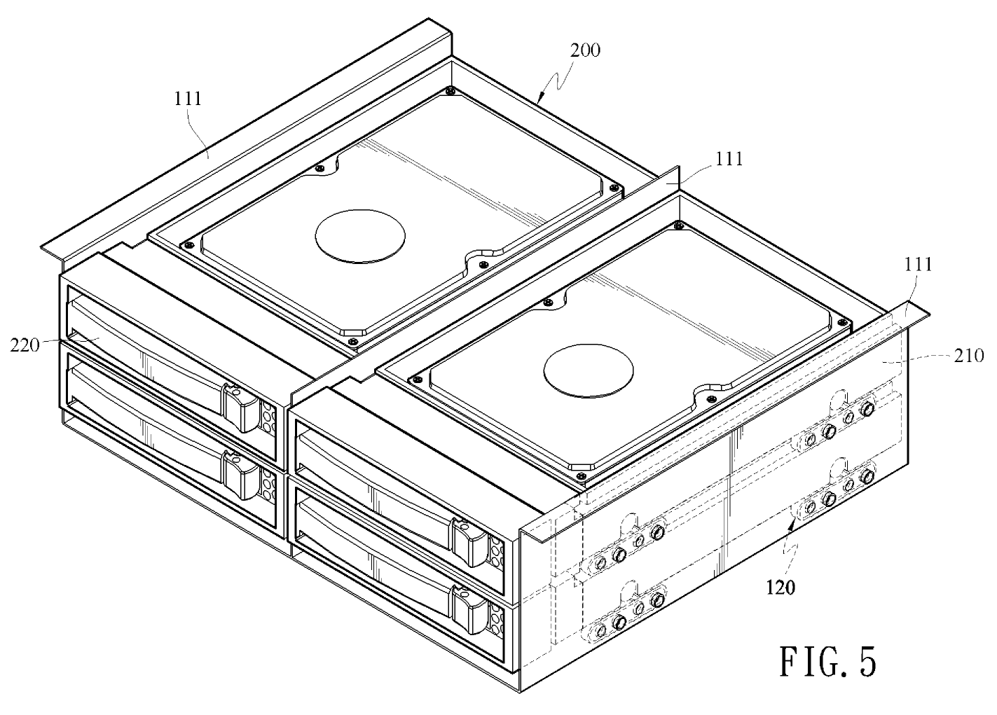

FIGS. 4 and 5 show the supporting apparatus with the shock isolation function according to a second embodiment of the present invention, which is applicable for supporting a plurality of storage devices 200. The supporting apparatus with the shock isolation function according to the second embodiment of the present invention includes a frame body 110 and a plurality of supporting parts 120 disposed in pairs. The frame body 110 has a plurality of side plates 111, and the side plates 111 are equidistantly spaced apart with each other to form a plurality of accommodating spaces with the same width as that of the storage device 200. At least one protruding point 112 is respectively protruded from two opposite sides of each side plate 111, and the protruding points 112 on the two opposite sides are alternately arranged and equidistantly spaced apart on the same horizontal position. A plurality of groups of protruding points 112 is selectively disposed on the side plate 111 at a height satisfying the size of the storage device 200.

Each supporting part 120 has a main body 121 and an elastic washer 122, and the main body 121 has a plurality of joint holes 1211 opened corresponding to the protruding points 112 that is provided selectively for the protruding points 112 at any side of the side plate 111 to be engaged in, such that the supporting parts 120 may be respectively fixed at the contour position for two opposite sides of the side plate 111. According to the practical number of the storage devices 200, a plurality of spaces for accommodating a single storage device 200 is alternately formed. When the storage device 200 is placed between two neighboring side plates 111, a pair of supporting parts 120 just supports the bottom surface of the storage device 200 at two sides of the storage device 200. The elastic washer 122 is sleeved on the outer periphery of the main body 121, and mutually contacts with the storage device 200, so as to absorb the external shocking energy, or the shocking energy generated by the storage device 200 itself.

Referring to FIGS. 4 and 5, the protruding points 112 on the side plate 111 are formed by means of directly performing the punching process on predetermined positions of the side plate 111 for the two sides, such that the side plate 111 is pressed to be deformed to form a plurality of alternately arranged protruding points 112. In addition, the two ends of the main body 121 of the supporting part 120 are fabricated as circular arc-shaped. When some deviation of position or angle occurs when the storage device 200 is pushed into the frame body 110, the main body 121 with the circular arc-shaped end surface may guide the slide tracks 210 at two sides of the storage device 200 to smoothly slide to positions above the supporting part 120, such that the supporting part 120 supports the storage device 200 in the accommodating space formed by two neighboring side plates 111. The fixing component 220 is used to buckle with the positioning hole 113 on the side plate 111, such that the storage device 200 may be fixed in the frame body 110.

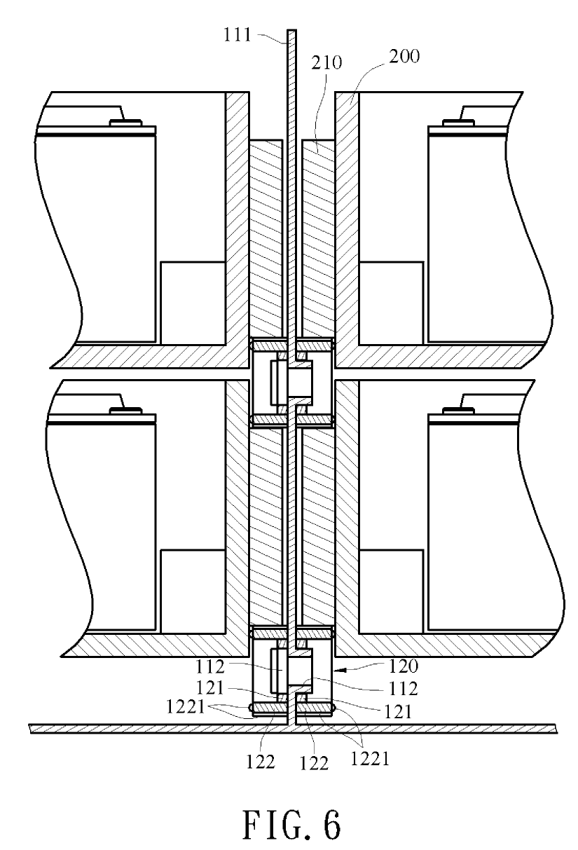

As shown in FIG. 6, it is a schematic sectional view of the second embodiment of the present invention. A plurality of rib-shaped shock absorbing portions 1221 with the shape similar to protruding points is equidistantly disposed on the surface of the elastic washer 122, such that the shock absorbing portion 1221 on the surface of the elastic washer 122 mutually contacts with the slide tracks 210 of the two neighboring storage device 200, thereby increasing the deformation of the elastic washer 122, and improving the effect of absorbing the shocking energy of the elastic washer 122. The height of the elastic washer 122 protruding from the side plate 111 is higher than the height of the main body 121 protruding from the side plate 111, so as to prevent the storage device 200 from directly contacting with the main body 121 or the side plate 111, such that the shock energy can be absorbed, and the energy must be transmitted through the elastic washer 122 to the side plate 111 and the storage device 200, thereby improving the shock isolation and absorbing effect of the elastic washer 122.

In the supporting apparatus with the shock isolation function provided by the present invention, a plurality of protruding points alternately arranged and disposed at different heights is pre-protruded from the two sides of the side plate in the frame body, for the plurality of supporting parts to be engaged on the side plate, and forming the plurality of accommodation spaces with the side plates for accommodating a single storage device, such that a plurality of storage devices may be fixed in the frame body with the contour interval on two opposite sides of the side plate. Therefore, the utilizing space in the frame body is increased, and the supporting part further provides a shock absorbing protection effect, so as to prevent the storage device installed in the frame body from being affected by the shocking energy and being damaged.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A supporting apparatus with a shock isolation function, applicable for supporting at least one storage device, comprising:
a frame body, having two opposite side plates, and at least one protruding point protruded from one side surface of the two side plates that are facing each other, wherein the storage device is accommodated between the two side plates; and
at least two supporting parts, each having:
a main body, having at least one joint hole for the protruding point to be engaged in, such that the two supporting parts are respectively fixed on the two side plates, wherein the two supporting parts support a bottom surface of the storage device at two sides of the storage device; and
an elastic washer, sleeved on an outer periphery of the main body and contacting with the storage device, for absorbing a shocking energy.

2. The supporting apparatus with the shock isolation function as claimed in claim 1, wherein a plurality of shock absorbing portions is protruded from a surface of the elastic washer.

3. The supporting apparatus with the shock isolation function as claimed in claim 1, wherein two ends of the main body are circular arc-shaped.

4. The supporting apparatus with the shock isolation function as claimed in claim 1, wherein height of the elastic washer protruding from the side plate is larger than height of the main body protruding from the side plate.

5. The supporting apparatus with the shock isolation function as claimed in claim 1, wherein the elastic washer is made of rubber.

6. A supporting apparatus with a shock isolation function, applicable for supporting at least one storage device, comprising:
a frame body, having a plurality of side plates alternately arranged to form a plurality of accommodating spaces with a same width as the storage device, and having at least one protruding point respectively protruded from two sides of each side plate, wherein the storage device is accommodated between two neighboring side plates; and
a plurality of supporting parts disposed in pairs, wherein each supporting part has:
a main body, having at least one joint hole for the protruding point to be engaged in, such that each of the supporting parts is respectively fixed on each side plate, wherein each pair of supporting parts fixed on two neighboring side plates supports a bottom surface of the storage device at two sides of the storage device; and
an elastic washer, sleeved on an outer periphery of the main body and contacting with the storage device, for absorbing a shocking energy.

7. The supporting apparatus with the shock isolation function as claimed in claim 6, wherein a plurality of shock absorbing portions is protruded on a surface of the elastic washer.

8. The supporting apparatus with the shock isolation function as claimed in claim 6, wherein two ends of the main body are circular arc-shaped.

9. The supporting apparatus with the shock isolation function as claimed in claim 6, wherein height of the elastic washer protruding from the side plate is larger than height of the main body protruding from the side plate.

10. The supporting apparatus with the shock isolation function as claimed in claim 6, wherein the elastic washer is made of rubber.
